(19) United States
(12) Patent Application Publication
(10) Pub. No.: US 2012/0264303 A1
(43) Pub. Date: Oct. 18, 2012

(54) CHEMICAL MECHANICAL POLISHING SLURRY, SYSTEM AND METHOD

(75) Inventors: Kei-Wei CHEN, Tainan City (TW); Kuo-Hsiu WEI, Tainan City (TW); Shih-Chieh CHANG, Taipei City (TW); Ying-Lang WANG, Lung-Jing Country (TW)

(73) Assignee: TAIWAN SEMICONDUCTOR MANUFACTURING CO., LTD., Hsin-chu (TW)

(21) Appl. No.: 13/087,565

(22) Filed: Apr. 15, 2011

(51) Int. Cl. H01L 21/306; B24D 11/00; C09K 13/00

(52) U.S. Cl. 438/693; 252/79.1; 451/526; 257/E21.23

(57) ABSTRACT

A metal polishing slurry includes a chemical solution and abrasives characterized by a bimodal or other multimodal distribution of particle sizes or a prevalence of two or more particle sizes or ranges of particle sizes. A method and system for using the slurry in a CMP polishing operation, are also provided.

### TECHNICAL FIELD

The disclosure is related to a system, method and slurry used in chemical mechanical polishing (CMP) of semiconductor devices.

### BACKGROUND

Chemical mechanical polishing, CMP, is commonly used in the semiconductor manufacturing industry to polish and remove metal or other materials from over a surface of a semiconductor substrate upon which semiconductor devices are being fabricated. Most commonly, conductive interconnect patterns are formed on semiconductor devices by forming a series of openings, such as vias and trenches in an insulating material disposed on a substrate surface, and then forming a conductive layer over the substrate surface and filling the openings. Damascene technology involves removing the conductive material from over the surface such that the conductive material remains only in the openings to form conductive structures such as various plugs and leads that serve as interconnection patterns and vias. CMP is also used extensively for planarizing shallow trench isolation regions.

When polishing to remove metal materials from over the substrate surface, it is critical to ensure that no metal residue remains over the surface as this can cause bridging between otherwise isolated conductive features, resulting in short circuits. It is also critical to ensure that dishing is avoided. Dishing involves the formation of a concave surface in the top surface of the conductive feature and can create topography problems in subsequent processing.

One way to prevent the occurrence of defects such as the aforementioned defects, is to ensure that the metal removal rate is uniform and consistent during polishing and does not diminish over time. During polishing, the metal removal rate depends on a number of factors including but not limited to the chemistry of the polishing solution, the amount of oxidation caused by the chemistry of the polishing slurry, and the degree of mechanical wearing caused by the abrasives in the slurry.

Common drawbacks of current polishing technologies include inconsistent metal removal rates and polishing rates that do not remain constant over time.

### BRIEF DESCRIPTION OF THE DRAWINGS

The present disclosure is best understood from the following detailed description when read in conjunction with the accompanying drawing. It is emphasized that, according to common practice, the various features of the drawing are not necessarily to scale. On the contrary, the dimensions of the various features may be arbitrarily expanded or reduced for clarity. Like numerals denote like features throughout the specification and drawing.

FIG. 1 is a graph showing an exemplary bimodal distribution of abrasive particles of an exemplary slurry;

FIG. 2 is a plan view showing a portion of an exemplary polishing slurry that includes abrasive particles in bimodal distribution;

FIGS. 3A-3C are cross-sectional views showing an exemplary polishing operation and system. FIG. 3A shows a semiconductor substrate being polished.

FIGS. 3B and 3C are expanded views showing a portion of FIG. 3A. FIG. 3B shows the abrasive particles of the slurry during an exemplary polishing operation and FIG. 3C shows the abrasive particles of a slurry when pressure is applied during a polishing operation; and

FIG. 4 graphically depicts comparative removal rates including the removal rate produced by an exemplary embodiment of the disclosed slurry.

### DETAILED DESCRIPTION

The disclosure provides a polishing slurry advantageously used in the chemical mechanical polishing of metal materials or other materials, in the semiconductor manufacturing industry. In addition to copper and aluminum, the slurry may be used for polishing other materials, such as silicon dioxide, tungsten, or carbon nanotubes. The polishing slurry includes a chemical solution and abrasives. The polishing slurry may be used in the chemical mechanical polishing of various metals, metal alloys and other conductive and semiconductor materials and may be referred to as a metal polishing slurry in some embodiments. The polishing slurry is chemically reactive toward metal or other material being polished, and may include surfactants, oxidizers, metal corrosion inhibitors, enhancers, and other suitable materials that are used in polishing slurries. The polishing slurry includes abrasive particles and, in some embodiments, the abrasive particles are present in a bimodal or multimodal distribution. There may be two prevalent different particle sizes among the particles that make up the abrasives or there may be two prevalent particle size ranges among the particles that make up the abrasives. There may be a bimodal distribution of abrasive particles in which there are two predominant populations of particles, one population representing a first range of particle sizes and another population representing a second range of particle sizes.

The disclosure also provides a method for removing metal or another conductive or non-conductive material from over the surface of a semiconductor substrate by polishing using the slurry. Also provided is a system including a CMP polishing tool, a semiconductor wafer with metal or another conductive material formed over the surface thereof, and the aforementioned polishing slurry.

Provided is a polishing slurry useful in CMP operations for polishing various metals, alloys or other conductive materials, or dielectric materials (such as silicon dioxide). According to some embodiments, during the CMP operation using the polishing slurry to remove metal, metal is removed from over a surface of a semiconductor substrate. The metal may advantageously be formed over a dielectric or insulating layer that includes openings therein. The openings may be in the form of contacts, vias, trenches and other openings. The polishing operation may be used to remove the metal material from over the surface such that the metal remains only in the openings to form structures such as plugs and leads that serve as interconnection patterns, contacts and vias in accordance with damascene processing technology. The metal may be any of various metals used in semiconductor manufacturing including but not limited to copper, aluminum, molybdenum, tungsten, tantalum, and other suitable metal materials and metal alloys.

The polishing slurry includes a chemical solution and abrasives. The polishing slurry may be a metal polishing slurry that is chemically reactive toward the metal material it is used to remove but may also include oxidizers or other components that reduce the metal polishing rate. According to various exemplary embodiments, the polishing slurry may include surfactants, oxidizers, metal corrosion inhibitors, enhancers, and abrasives. The surfactants may be formed of alkylphenol ethoxylates and their derivatives, the oxidizers may be peroxide or other suitable materials, the metal corrosion inhibitors may be benzotrialole or its derivatives and the enhancers may be glycine or related amino acids. It should be understood that the proceeding examples are intended to be exemplary only and other surfactants, oxidizers, metal corrosion inhibitors and enhancers may be used in other exemplary embodiments and further components may also be included in the polishing slurry.

The abrasives are particles that may be formed of silica, including fumed silica or colloidal silica according to exemplary embodiments. In other exemplary embodiments such as in slurries directed to polishing/removing copper, the abrasive particles may be formed of Al₂O₃ or other suitable materials. One aspect of the disclosure is that the abrasives in the polishing slurry are characterized by a bimodal distribution of particle sizes. The abrasives in the polishing slurry may also be characterized as including a prevalence of two different sized particles or two different ranges of particle sizes that are most prevalent. By prevalence of two particle sizes or two ranges of particle sizes, it is meant that each of two particle sizes or ranges of particle sizes, is present in a population much greater than the population of any other particle size or particle size range, although relative populations may vary. In one exemplary embodiment, the population of each of the most prevalent particle sizes or ranges may be at least 60% greater than any other particle size or particle size range, but this is intended to be exemplary only. In one exemplary embodiment, the population of each of the most prevalent particle sizes or ranges may be at least 40% greater than any other particle size or particle size range. The distribution of particle sizes that make up the abrasives, may be bimodal in nature, according to various exemplary embodiments. Generally speaking, there is a preponderance of two different abrasive particle sizes, or ranges of particle sizes, in the metal polishing slurry.

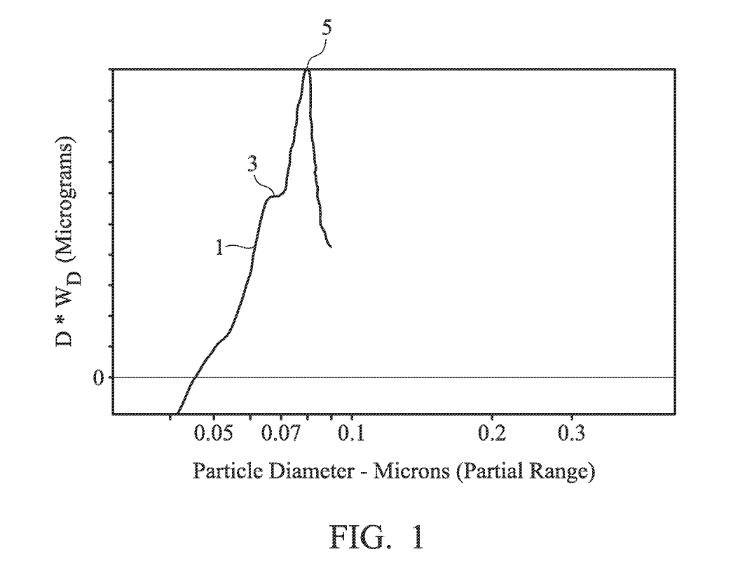

FIG. 1 is a graph showing an exemplary bimodal distribution of particle sizes in the slurry. The particle sizes are given in diameter. Distribution curve 1 shows local maximums at points 3 and 5. The particle size at local maximum point 3 may be about 0.063 microns in diameter and the particle size at local maximum point 5 may be about 0.08 microns in diameter. This is intended to be exemplary only and in other exemplary embodiments, the two prevalent particle sizes may vary. Each local maximum point 3,5 represents a mode on the exemplary bimodal distribution curve 1, and therefore a peak particle size and associated range. Local maximum point 3 may represent a peak particle size of about 0.06 microns and a first population of particles having diameters ranging from about 0.05 to about 0.07 microns and local maximum point 5 may represent peak particle size of about 0.08 microns and a second population of particles having diameters ranging from about 0.05 to about 0.10 microns. According to various other exemplary embodiments, the bimodal distribution of particles may include local maxima, i.e. inflection points in bimodal distribution curve 1, at other locations. According to another exemplary embodiment, the two most prevalent particle sizes such as associated with local maxima may be about 0.05 microns and about 0.075 microns and according to another exemplary embodiment, the most prevalent particle sizes associated with local maxima may be about 0.05 microns and about 0.10 microns, and according to yet another exemplary embodiment, the two most prevalent particle sizes as associated with local maxima may be about 0.06 microns and about 0.08 microns. In another embodiment, the two most prevalent particle sizes associated with local maxima may be about 0.075 microns and about 0.1 microns.

In other exemplary embodiments, there may not be a continuous distribution of particle sizes but rather only a limited number of discrete particle sizes. In one exemplary embodiment, the abrasives may consist entirely of two particle sizes. In another exemplary embodiment, the two most prevalent particle sizes may constitute 75% of all abrasive particles and in yet another exemplary embodiment, the two most prevalent particle sizes may constitute 90% of all abrasive particles.

The relative populations of the two most prevalent particle sizes will vary in the exemplary embodiments. In FIG. 1, while there is an overlap of the two modes having local maxima at points 3 and 5 in the exemplary bimodal distribution, the population of particles represented by local maximum point 3 may be about 60% of the population of particles represented by local maximum point 5. In the illustrated embodiment, local maximum point 3 may include a height that is about 60% of the height of local maximum point 5. It should be understood that distribution curve 1 is just one way to show particle distribution in one exemplary embodiment. In other exemplary embodiments, the distribution of abrasive particles will be described by other curves and the ratio between the two most prevalent particle sizes may be 1:1, 2:1, 3:1, 4:1 or various other ratios. An aspect of the polishing slurry is that, in addition to the chemical solution, the abrasives include a prevalence of two different size abrasive particles or two different ranges of abrasive particle sizes. In some exemplary embodiments, the distribution of particle sizes that constitute the abrasive, may be illustrated by a bimodal distribution on a continuous particle size distribution curve whereas in other exemplary embodiments there may be two or more discrete particle sizes. The disclosed abrasives are not limited to any two particular particle sizes or any two ranges of particle sizes and they are not limited to any particular ratio between the populations of the two prevalent particles, or distributions of particle sizes. Further, while the two most prevalent particle sizes or particular size ranges are more prevalent than any other particle size or range of particle sizes, the degree by which they are more prevalent than other particle sizes or particle size ranges may also vary.

In other exemplary embodiments, the abrasive particles may be characterized by a multimodal distribution of particle sizes, i.e. there may be three or more modes. In some embodiments, the abrasives in the polishing slurry may include a prevalence of three or more different sized particles or three or more different ranges of particle sizes that are most prevalent.

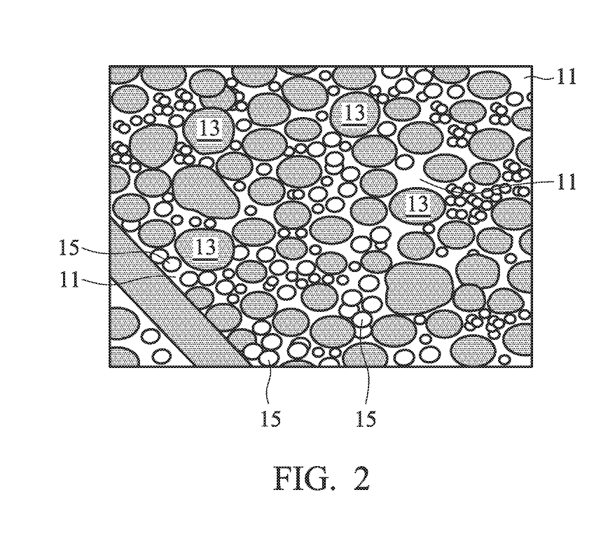

FIG. 2 is a plan view showing an exemplary embodiment of a polishing slurry including the abrasive particles. Polishing slurry 11 includes a chemical solution and a plurality of abrasive particles and it can be seen that the polishing slurry includes particles of various sizes but there is a prevalence of larger particles 13 and smaller particles 15. Although all larger particles 13 may not be the exact same size and although all smaller particles 15 may not be the exact same size, each represents a population of similarly sized particles (i.e. a range of particle sizes) such as may be in a bimodal distribution as in one exemplary embodiment as illustrated in FIG. 2. This illustration is intended to be exemplary only and other exemplary embodiments will include different particle size distributions and still other exemplary embodiments may not include a distribution of particle sizes, but rather will include only particles with two or more different sizes.

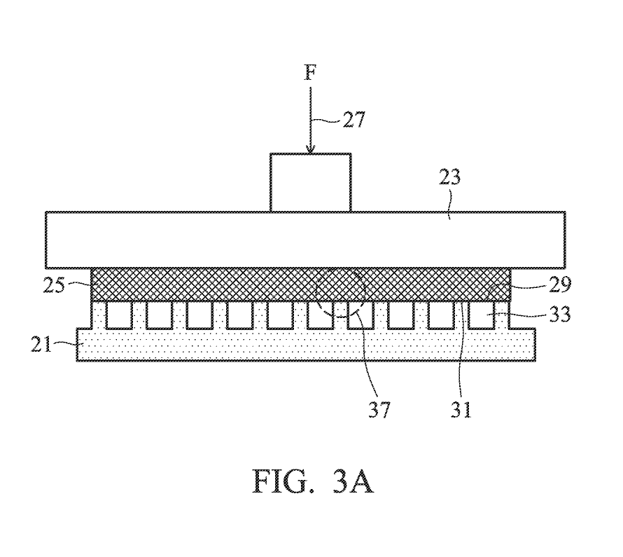

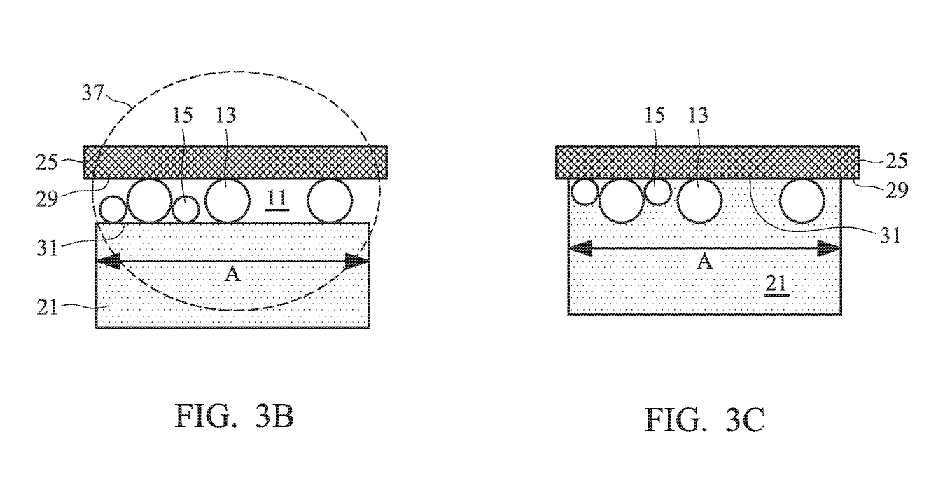

Also disclosed is a method and apparatus for using the polishing slurry in a polishing operation. FIG. 3A shows a portion of a CMP apparatus including polishing pad 21 and stage 23. Stage 23 receives semiconductor substrate 25. In the illustrated embodiment stage 23 may be sized to accommodate one or multiple semiconductor substrates and the substrates may be various sized semiconductor substrates. The system includes means for providing force indicated by arrow 27 which urges polishing pad 21 and stage 23 toward one another. Semiconductor substrate 25 includes substrate surface 29 which contacts polishing pad surface 31. Polishing pad 21 includes polishing surface 31 and also includes grooves 33 according to various exemplary embodiments.

FIG. 3B is an expanded view showing a close up of portion 37 of FIG. 3A. Polishing slurry 11 is introduced between polishing pad 21 and semiconductor substrate 25, in particular between polishing surface 31 and substrate surface 29. Polishing slurry 11 includes abrasives, in particular a prevalence of larger abrasive particles 13 and smaller abrasive particles 15. As polishing takes place, i.e. polishing pad 21 and semiconductor substrate or substrates 25 are rotated with respect to one another, force may be applied as shown in FIG. 3A to initially produce the arrangement shown in FIG. 3B. Additional force is applied to produce the arrangement shown in FIG. 3C. Polishing pad 21 may be formed of polyurethane or other suitable deformable material and during the polishing operation as illustrated in FIG. 3C, the abrasive particles, i.e. larger particles 13 and smaller particles 15 may become at least temporarily embedded within polishing surface 31 of polishing pad 21. Polishing pad 21 may advantageously be formed of a resilient material that may be elastically deformable and therefore not permanently deformed. According to other exemplary embodiments, larger particles 13 and smaller particles 15 of the abrasive particles, may only become partially indented into polishing surface 31 of polishing pad 21.

The disclosed polishing slurry with a prevalence of two particle sizes produces a generally constant removal rate of the metal or other material being polished. Applicants have discovered that one exemplary embodiment of the disclosed polishing slurry with bimodal particle distribution, produces a generally constant metal removal rate when metal is removed during a CMP operation.

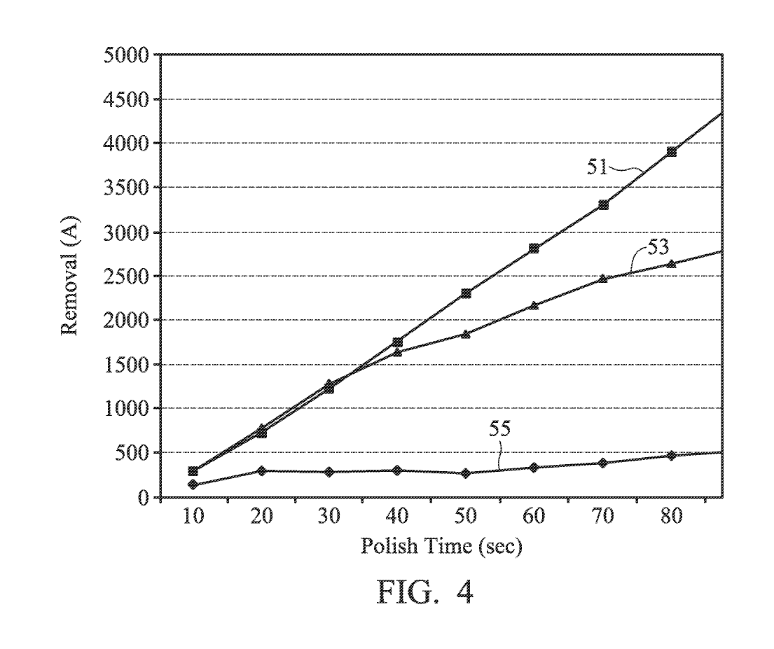

FIG. 4 is an exemplary line graph showing removal rates for an exemplary metal polishing slurry with a bimodal distribution of particles compared to a slurry having one particle size and compared to a slurry with no abrasive particles. The graph is directed to a copper polishing operation but such is exemplary only and the relatively constant removal rate for copper indicated by the disclosed slurry with the bimodal particle size distribution for abrasives, is also achievable when polishing other materials or using other particle size combinations. The graph presents removal amount as a function of polishing time and includes line 51 indicative of a polishing operation using the disclosed metal polishing slurry, line 53, representative of a slurry with one particle size, and line 55 representative of a slurry without abrasive particles. The relatively straight line for line 51 compared to lines 53 and 55, indicates a relatively constant removal rate whereas lines 53 and 55 tail downwardly and indicate a drop-off in removal rate. This graph is understood to be exemplary only and in other exemplary embodiments, other polishing rates may be achieved depending on the metal material polished and the various components that enhance or inhibit polishing that may form part of the chemical solution of the slurry.

In one aspect, a CMP (chemical mechanical polishing) slurry is provided. The slurry comprises a chemical solution with abrasive particles, the abrasive particles characterized by a multimodal distribution of particle sizes.

A method for chemical mechanical polishing, CMP, is also provided. The method comprises providing a CMP apparatus, disposing a semiconductor substrate in the CMP apparatus, the semiconductor substrate including a metal or other material formed over a substrate surface thereof. The method further comprises introducing a slurry to the CMP apparatus and covering the substrate surface, the slurry comprising a chemical solution with abrasives, the abrasives including a multimodal distribution of particle sizes, and polishing the substrate surface in the CMP apparatus using the slurry.

Also provided is a system for chemical mechanical polishing (CMP) of conductive materials, comprising a CMP apparatus, including a polishing pad with grooves therein and a stage for receiving a semiconductor wafer thereon and in confronting relation with the pad, and a slurry disposed on the pad, the slurry comprising a chemical solution with abrasives, the abrasives including a bimodal distribution of particle sizes.

The preceding merely illustrates the principles of the disclosure. It will thus be appreciated that those skilled in the art will be able to devise various arrangements which, although not explicitly described or shown herein, embody the principles of the disclosure and are included within its spirit and scope. For example the disclosed polishing slurry may also be used for polishing other materials used in the manufacture of semiconductor devices.

Furthermore, all examples and conditional language recited herein are principally intended expressly to be only for pedagogical purposes and to aid in understanding the principles of the disclosure and the concepts contributed by the inventors to furthering the art, and are to be construed as being without limitation to such specifically recited examples and conditions. Moreover, all statements herein reciting principles, aspects, and embodiments, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. The drawings are arbitrarily oriented for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the disclosure has been described in terms of exemplary embodiments, it is not limited thereto. Rather, the appended claims should be construed broadly, to include other variants and embodiments, which may be made by those skilled in the art without departing from the scope and range of equivalents.

What is claimed is:

1. A CMP (chemical mechanical polishing) slurry comprising a chemical solution with abrasive particles, said abrasive particles characterized by a multimodal distribution of particle sizes.

2. The CMP slurry as in claim 1, wherein said multimodal distribution of particle sizes includes a local maximum at a particle size of about 0.08 microns in diameter and a local maximum at a particle size of about 0.06 microns in diameter.

3. The CMP slurry as in claim 1, wherein said CMP slurry is a metal slurry and said multimodal distribution comprises a bimodal distribution of particle sizes that includes a first mode of particle sizes ranging from about 0.075 to 0.085 microns in diameter and a second mode of particle sizes ranging from about 0.055 to 0.065 microns in diameter.

4. The CMP slurry as in claim 1, wherein said multimodal distribution comprises a bimodal distribution of particles that includes a first population of first particles lying within a first range of particle sizes and being the most populous range of particle sizes, and a second population of second particles lying within a second range of particle sizes and comprising about 60% of said first population.

5. The CMP slurry as in claim 1, wherein said multimodal distribution of particle sizes is described by a bimodal distribution curve that includes a first population of first particles at a first local maximum and a second population of second particles at a second local maximum, wherein said second local maximum includes a height being at least 60% of a height of said first local maximum.

6. The CMP slurry as in claim 1, wherein said CMP slurry is a metal polishing slurry and further comprises surfactants, oxidizers, metal corrosion inhibiters and enhancers.

7. The CMP slurry as in claim 6, wherein said surfactants comprise at least one of alkylphenol ethoxylates and their derivatives, said oxidizers comprise hydrogen peroxide, said metal corrosion inhibiters comprise at least one of benzotrialole and its derivatives and said enhancers comprise at least one of glycine and related amino acids.

8. The CMP slurry as in claim 1, wherein said abrasive particles comprise one of colloidal silica and fumed silica.

9. The CMP slurry as in claim 1, wherein said CMP slurry comprises a slurry that is chemically reactive toward metal.

10. A method for chemical mechanical polishing, CMP, comprising:
providing a CMP apparatus;
disposing a semiconductor substrate in said CMP apparatus, said semiconductor substrate comprising a material formed over a substrate surface thereof;
introducing a slurry to said CMP apparatus and covering said substrate surface, said slurry comprising a chemical solution with abrasive particles, said abrasive particles characterized by a multimodal distribution of particle sizes; and
polishing said substrate surface in said CMP apparatus using said slurry.

11. The method as in claim 10, wherein said material comprises metal further fills openings formed on said substrate surface and said polishing comprises removing said metal from over said substrate surface but not from said openings.

12. The method as in claim 11, wherein said multimodal distribution of particle sizes comprises a bimodal distribution of particle sizes that includes a particle size distribution of about 0.08+/−0.01 micron diameter and a particle size distribution of about 0.06+/−0.01 micron diameter, as particle size distributions that occur most frequently in said bimodal distribution.

13. The method as in claim 11, wherein said multimodal distribution of particle sizes is described by a bimodal distribution curve that includes a local maximum at a particle size of about 0.08 microns and a local maximum at a particle size of about 0.06 microns.

14. The method as in claim 10, wherein said multimodal distribution of particle sizes comprises a bimodal distribution of particles that includes a first population of first particles lying within a first range of particle sizes and a second population of second particles lying within a second range of particle sizes and comprising at least about 60% of said first population.

15. The method as in claim 10, wherein said slurry is a metal polishing slurry and further comprises surfactants, oxidizers, metal corrosion inhibiters and enhancers.

16. The method as in claim 15, wherein said surfactants comprise at least one of alkylphenol ethoxylates and their derivatives, said oxidizers comprise hydrogen peroxide, said metal corrosion inhibiters comprise at least one of benzotrialole and its derivatives, said enhancers comprise at least one of glycine and related amino acids, and said abrasives comprise one of colloidal silica and fumed silica.

17. A system for chemical mechanical polishing (CMP) of conductive materials comprising:
a CMP apparatus including a polishing pad with grooves therein and a stage for receiving a semiconductor wafer thereon and in confronting relation with said polishing pad; and
a slurry disposed on said polishing pad, said slurry comprising a chemical solution with abrasive particles, said abrasive particles characterized by a bimodal distribution of particle sizes.

18. The system as in claim 17, wherein said bimodal distribution of particle sizes includes two populations of particles that are most prevalent in said bimodal distribution including a first population of particles having diameters ranging from about 0.05 to 0.07 microns and a second population of particles having diameters ranging from about 0.07 to 0.09.

19. The system as in claim 17, wherein said slurry is chemically reactive toward metal and said bimodal distribution of particle sizes is described by a bimodal distribution curve that includes a first local maximum at a particle size of about 0.08 microns and a second local maximum at a particle size of about 0.06 microns, and
said first local maximum represents a first population of first particles and said second local maximum represents a second population of second particles, wherein said second population comprises at least about 60% of said first population.

20. The system as in claim 17, wherein said slurry comprises a metal polishing slurry and further comprises surfactants, oxidizers, metal corrosion inhibitors and enhancers and wherein said CMP apparatus further comprises means for urging said stage toward said pad.
